(19) United States
(12) Patent Application Publication
(10) Pub. No.: US 2021/0117320 A1
(43) Pub. Date: Apr. 22, 2021

(54) CONSTRUCTION OF A BLOCK DEVICE

(71) Applicant: Micron Technology, Inc., Boise, ID (US)

(72) Inventor: Ananda C. S. Mahesh, Cedar Park, TX (US)

(21) Appl. No.: 16/660,147

(22) Filed: Oct. 22, 2019

(51) Int. Cl. G06F 12/06

(52) U.S. Cl. CPC G06F 12/0646; G11C 16/0483; G06F 2212/1041

(57) ABSTRACT

Disclosed embodiments relate to constructing an allocation of memory in a memory subsystem. In one example, a method includes receiving from a host system among a pool of host systems, a request to construct an allocation of memory, the pool of host systems being coupled to a pool of memory devices, selecting multiple memory devices among the pool of memory devices, selecting multiple memory components among the multiple memory devices, aggregating the multiple memory components to implement the allocation of memory, and providing, to the host system, hierarchical addresses to be used to access the multiple memory components implementing the allocation of memory, the hierarchical addresses each including a device ID of an associated memory device and a host ID of an associated host system.

### TECHNICAL FIELD

The present disclosure generally relates to construction of a block device in a memory subsystem and, more specifically, relates to implementing a block device with heterogeneous media.

### BACKGROUND ART

A memory subsystem can include one or more memory components within memory devices that store data. The memory components can be, for example, non-volatile memory components and volatile memory components. In general, a host system can utilize a memory subsystem to store data at the memory components and to retrieve data from the memory components.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing environment that includes a memory subsystem in accordance with some embodiments of the present disclosure.

FIG. 2 illustrates an initial allocation of multiple heterogeneous memory components to host a block device in accordance with some embodiments of the present disclosure.

FIG. 3 illustrates a modified block device configuration in accordance with some embodiments of the present disclosure.

FIG. 4 is a flow diagram of an example method to construct a heterogeneous block device in accordance with some embodiments of the present disclosure.

FIG. 5 illustrates an initial allocation of heterogeneous memory components across multiple host systems to form a block device in accordance with some embodiments of the present disclosure.

FIG. 6 illustrates a modified block device configuration in accordance with some embodiments of the present disclosure.

FIG. 7 is a flow diagram of an example method to construct a heterogeneous block device in accordance with some embodiments of the present disclosure.

FIG. 8 is a block diagram of an example computer system in which embodiments of the present disclosure can operate.

### DETAILED DESCRIPTION

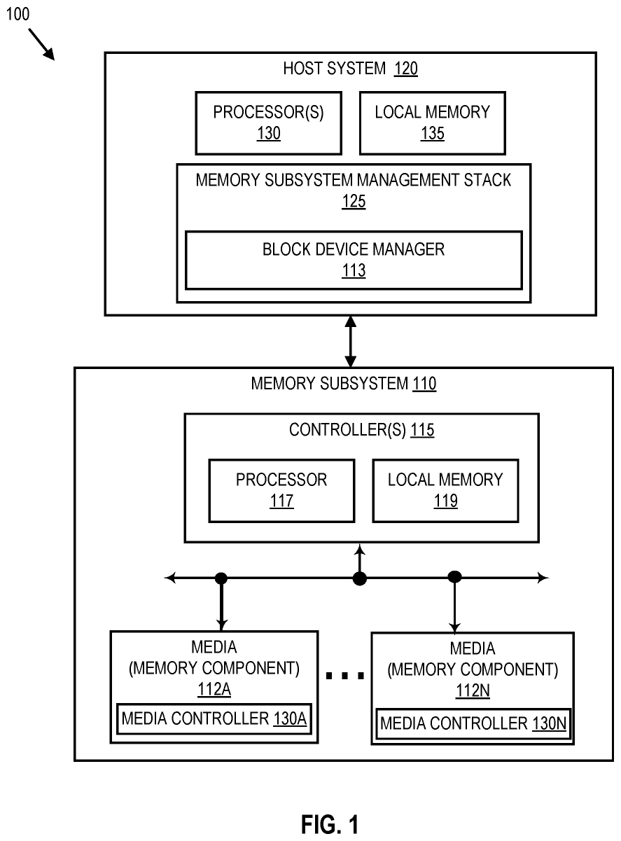

Aspects of the present disclosure are directed to construction of a heterogeneous block device in a memory subsystem. A memory subsystem is also hereinafter referred to as a “memory device” or “memory devices.” An example of a memory subsystem is one or more memory modules that are connected to a central processing unit (CPU) via a memory bus. A memory subsystem can be a storage device, a memory module, or a hybrid of a storage device and memory module. Examples of storage devices and memory modules are described below in conjunction with FIG. 1. In general, a host system can utilize a memory subsystem that includes one or more memory devices. The memory devices can include, for example, non-volatile memory devices, such as negative-AND (NAND) memory devices and write-in place memory devices, such as three-dimensional cross-point (“3D cross-point”) memory device, which is a cross-point array of non-volatile memory cells. Other types of memory devices, including volatile memory devices, are described in greater detail below in conjunction with FIG. 1. The host system can provide data to be stored at the memory subsystem and can request data to be retrieved from the memory subsystem.

As referred to herein, a block device is a quantity of non-volatile memory (NVM) that can be formatted into groups, physical units, chunks, and logical blocks. For example, a block device can be an abstraction of a portion of NVM (e.g., like a partition or other logical abstraction of physical storage resources) allocated to an application or use and written in formatted groups, such as blocks or other units of memory. In some contexts, a block device can be referred to as a namespace. Embodiments described below refer to a block device but are not limited to a particular definition of a “block.” As such, the term “block device” can be used interchangeably with the term “allocation of memory.”

Conventional block devices are constructed using homogeneous media within a memory subsystem. For example, when multiple types of non-volatile memory (NVM) (e.g., single-level cell (SLC) NAND flash, multi-level cell (MLC) NAND flash, triple-level cell (TLC) NAND flash, quad-level-cell (QLC) NAND flash, 3D XPoint, ReRAM (Resistive Random Access Memory), or NRAM (Nano-RAM), MRAM (Magneto resistive RAM), STT (spin torque transfer MRAM), MRAM, FRAM (Ferroelectric RAM) are available, each traditional block device uses just one media type. With such a limitation, conventional systems often fail to properly match the diverse needs of an application running on the host system.

Aspects of the present disclosure address the above and other deficiencies by constructing a heterogeneous block device using an aggregate of different media types, e.g., selecting media types that best match the needs of an application. For example, an application can use both a high density, high latency portion of storage as well as a low density, low latency portion of storage to implement storage tiering or caching within a block device.

Disclosed embodiments further support dynamic modification of the block device, allowing it, after being constructed with an initial selection of media types, to subsequently be expanded, contracted, thin-provisioned, duplicated, and migrated. In other words, memory components and memory devices can be added to or removed from the block device sometime after initially building the block device. Disclosed embodiments can respond to various triggers indicating needs to dynamically expand, contract, or rebuild the block device.

Advantageously, disclosed embodiments attempt to dynamically match the needs of the application on the host system, adapting the block device to changing requirements of the host system or failures in the components of the NVM.

FIG. 1 illustrates an example computing environment 100 that includes a memory subsystem 110 in accordance with some embodiments of the present disclosure. The memory subsystem 110 can include media, such as memory components 112A to 112N (also referred to as “memory devices”). The memory components 112A to 112N can be volatile memory components, non-volatile memory components, or a combination of such. A memory subsystem 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 (e.g., including a memory subsystem management stack 125) that is coupled to one or more memory subsystems 110. In some embodiments, the host system 120 is coupled to different types of memory subsystem 110. FIG. 1 illustrates one example of a host system 120 coupled to one memory subsystem 110. The host system 120 uses the memory subsystem 110, for example, to write data to the memory subsystem 110 and to read data from the memory subsystem 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), storage system processor, or such a computing device that includes a memory and a processing device. The host system 120 can include or be coupled to the memory subsystem 110 so that the host system 120 can read data from or write data to the memory subsystem 110. The host system 120 can be coupled to the memory subsystem 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), etc. The physical host interface can be used to transmit data between the host system 120 and the memory subsystem 110. The host system 120 can further utilize an NVM Express (NVMe) protocol interface to access the memory components 112A to 112N when the memory subsystem 110 is coupled with the host system 120 by the PCIe interface. The physical host interface can provide an interface for passing control, address, data, and other signals between the memory subsystem 110 and the host system 120.

The memory components 112A to 112N can include any combination of the different types of non-volatile memory components and/or volatile memory components. An example of non-volatile memory components includes a negative-and (NAND) type flash memory. Each of the memory components 112A to 112N can be, e.g., a die that includes one or more arrays of memory cells, such as single-level cells (SLCs), multi-level cells (MLCs), triple-level cells (TLCs), or quad-level cells (QLCs). Each of the memory cells can store one or more bits of data used by the host system 120. Although non-volatile memory components such as NAND type flash memory are described, the memory components 112A to 112N can be based on any other type of memory such as a volatile memory. In some embodiments, the memory components 112A to 112N can be, but are not limited to, random access memory (RAM), read-only memory (ROM), dynamic random access memory (DRAM), synchronous dynamic random access memory (SDRAM), phase change memory (PCM), magneto random access memory (MRAM), negative-or (NOR) flash memory, electrically erasable programmable read-only memory (EEPROM), ReRAM, NRAM (Nano-RAM, a resistive non-volatile random access memory), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. Furthermore, the memory cells of the memory components 112A to 112N can be grouped to form pages or that can refer to a unit of the memory component used to store data. With some types of memory (e.g., NAND), pages can be grouped to form blocks.

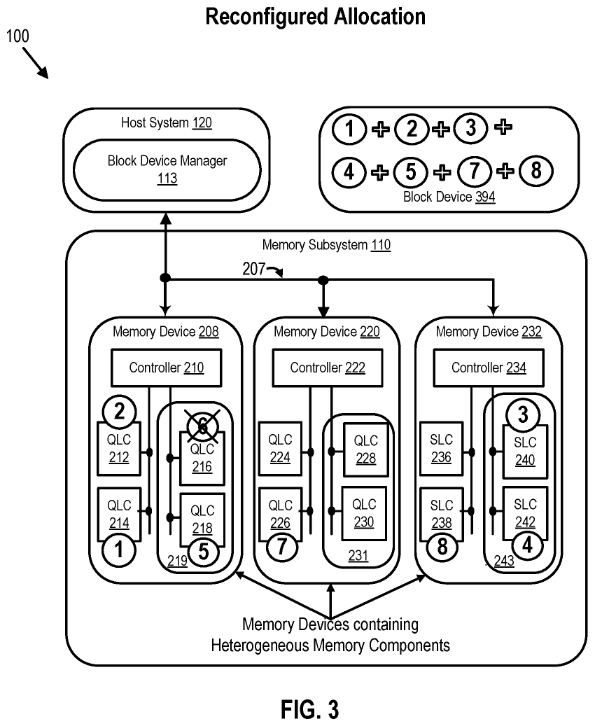

The memory system controller(s) 115 (hereinafter referred to as “controller” or “controllers”) can communicate with the memory components 112A to 112N to perform operations such as reading data, writing data, or erasing data at the memory components 112A to 112N and other such operations. In one embodiment, as described with reference to FIGS. 3-4 and 5-6, the memory subsystem 110 includes a controller 115 for a set of one or more memory components 112A to 112N of a particular media type. For example, the memory subsystem can include a first controller 115 to manage a set of one or more SLC memory components 112A to 112N, a second controller 115 to manage a set of one or more TLC memory components 112A to 112N, etc.

Each controller 115 can include hardware such as one or more integrated circuits and/or discrete components, a buffer memory, or a combination thereof. The controller 115 can be a microcontroller, special purpose logic circuitry (e.g., a field programmable gate array (FPGA), an application specific integrated circuit (ASIC), etc.), or another suitable processor. The controller 115 can include a processor (processing device) 117 configured to execute instructions stored in local memory 119. In the illustrated example, the local memory 119 of the controller 115 includes an embedded memory configured to store instructions for performing various processes, operations, logic flows, and routines that control operation of the memory subsystem 110, including handling communications between the memory subsystem 110 and the host system 120. In some embodiments, the local memory 119 can include memory registers storing memory pointers, fetched data, etc. The local memory 119 can also include read-only memory (ROM) for storing micro-code. While the memory subsystem 110 in FIG. 1 has been illustrated as including the controller 115, in another embodiment of the present disclosure, a memory subsystem 110 may not include a controller 115, and may instead rely upon external control for at least some of the management of memory components 112A to 112N (e.g., provided by a host, a processor, or a controller separate from the memory subsystem 110).

In general, the controller 115 can receive commands or operations from the host system 120 and can convert the commands or operations into instructions or appropriate commands to achieve the desired access to the memory components 112A to 112N. The controller 115 can be responsible for other operations such as wear leveling operations, garbage collection operations, error detection and error-correcting code (ECC) operations, encryption operations, deduplication operations, compression operations, caching operations, and address translations between a logical address (e.g., logical block address (LBA)) and a physical address (e.g., physical block address) that are associated with the memory components 112A to 112N. The controller 115 can further include host interface circuitry to communicate with the host system 120 via the physical host interface. The host interface circuitry can convert the commands received from the host system into command instructions to access the memory components 112A to 112N as well as convert responses associated with the memory components 112A to 112N into information for the host system 120.

Any one of the memory components 112A to 112N can include a media controller (e.g., media controller 130A and media controller 130N) to manage the memory cells of the memory components 112A-112N, to communicate with the memory subsystem controller 115, and to execute memory requests (e.g., read or write) received from the memory subsystem controller 115.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the controller 115 and decode the address to access the memory components 112A to 112N.

The host system 120 includes block device manager 113, which can allocate and manage a block device using memory components of heterogeneous media types. A block device manager is also hereinafter referred to as a “heterogeneous block device manager” or “heterogeneous block device managers.” In one embodiment, the block device manager 113 is a part of a memory subsystem management stack 125—e.g., a software stack or solution stack that provides address translations between a logical block address used by a host application and a physical block address associated with the memory subsystem 110 and its components 112A to 112N. For example, this can be the small computer system interface (SCSI) or NVMe block device management stack that allows the host system 120 to read/write to the memory subsystem in an abstracted manner. For example, the memory subsystem management stack 125 can be an Open-Channel memory system that also allows the host system 120 to control aspects that conventionally would be managed internally by the controller(s) 115, such as input/output scheduling, data placement, garbage collection, and wear leveling. The memory subsystem management stack 125 can be or include a microcontroller, special purpose logic circuitry (e.g., a field programmable gate array (FPGA), an application specific integrated circuit (ASIC), etc.), or another suitable processor. Additionally, one or more processor(s) 130 (processing devices) configured to execute instructions stored in local memory 135 can implement at least a portion of the memory subsystem management stack 125. For example, the processor(s) 130 can execute instructions stored in local memory 135 for performing the operations described herein. While the description herein focuses on the block device manager 113 being a part of the host system 120, in some embodiments, some or all of functionality of the block device manager 113 is implemented within the controller(s) 115. Further details with regards to the operations of the block device manager 113 are described below.

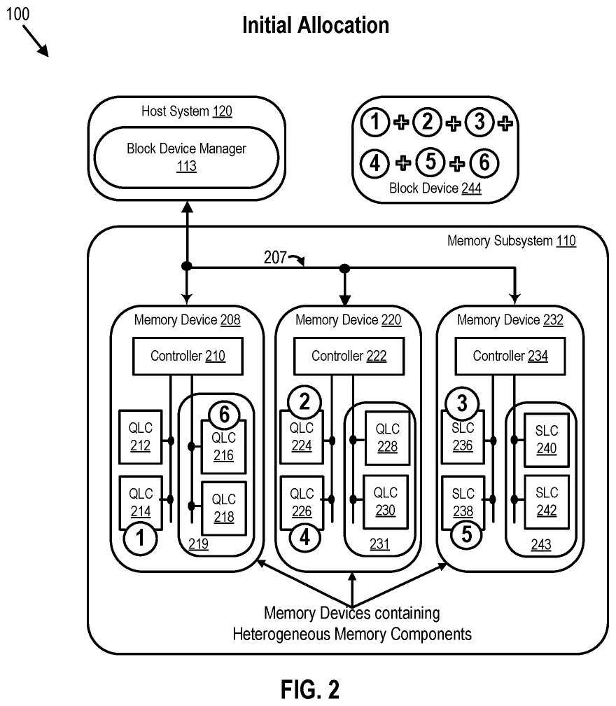

FIG. 2 illustrates an initial allocation of multiple heterogeneous memory components to host a block device, according to some embodiments. As shown, memory subsystem 110 is coupled to host system 120. Memory subsystem 110 is a detailed example of memory subsystem 110 described above and includes memory bus 207 coupling memory devices 208, 220, and 232 to the host system 120. Each of the memory devices 208, 220, and 232 includes a controller, shown as controllers 210, 222, and 234, which are examples of controller 115 described above. Each of memory devices 208, 220, and 232 includes a set of one or more memory components, which are examples of memory components 112A-112N, described above. In one embodiment, each of the memory devices 208, 220, and 232 is a memory module of a single type of media.

Memory device 208 includes controller 210 and four QLC memory components, 212, 214, 216, and 218. In some embodiments, as here, memory components 212, 214, 216, and 218 can be abstracted into parallel units by channel (as used herein, a parallel unit refers to a memory component within a channel). For example, different memory components can be coupled to the controller via different channels or groups, enhancing parallelism and throughput. Such groups provide another layer of addressing. QLC memory components 216 and 218 are a part of parallel unit 219. Memory device 208, according to disclosed embodiments, is not limited to having four memory components. In other embodiments, not shown, memory device 208 includes more QLC memory components.

Memory device 220 includes controller 222 and four QLC memory components, 224, 226, 228, and 230. QLC memory components 228 and 230 are a part of parallel unit 231. Memory device 220, according to disclosed embodiments, is not limited to having four memory components. In other embodiments, not shown, memory device 220 includes more QLC memory components.

Memory device 232 includes controller 234 and four SLC memory components, 236, 238, 240, and 242. SLC memory components 240 and 242 are a part of parallel unit 243. Memory device 232, according to disclosed embodiments, is not limited to having four memory components. In other embodiments, memory device 232 includes more SLC memory components.

Here, memory subsystem 110 is shown including QLC and SLC memory devices. Other embodiments include memory components having any of various media types, including SLC, MLC, TLC, or QLC flash memories, and/or a cross-point array of non-volatile memory cells, or other NVM, such as ReRAM or NRAM or MRAM or STT MRAM, FRAM. Typically, SLC memory components have higher performance, in terms of read and write latencies, than MLC, TLC, and QLC. QLC memory components can store 4 bits per cell, which yields higher capacity and lower cost per bit than SLC memory components. Accordingly, the illustrated memory component types decrease in cost and performance speed as bits stored per cell increase from SLC to MLC to TLC to QLC memory devices.

In operation, block device manager 113 receives, from host system 120, a request to construct a block device 244. For example, block device manager 113 constructs the block device 244 by allotting physical units, dice, and/or logical unit numbers (LUNs). In some embodiments, the memory devices 208, 220, and 232 make their internal storage resources visible to the host system 120. In some embodiments, host system 120 can discover the geometry of memory components within memory devices 208, 220, and 232, for example by issuing a geometry command to the memory devices. As used herein, “geometry” refers to the boundaries of groups, parallel units, and chunks in the memory devices. Host system 120 can then specify a requested geometry along with (or in addition to) the request to construct the block device.

In one embodiment, block device manager 113 selects multiple memory devices from among a pool of memory devices, including memory devices 208, 220, and 232, to implement the block device. From among the selected memory devices, block device manager 113 further selects multiple memory components to implement block device 244. As shown, block device manager 113 allocates portions of the memory devices, e.g., assigns physical units (PUs), dice, and/or logical unit numbers (LUNs) of six memory components to implement block device 244. The selected portions are sometimes referred to herein as allocations, allotments, or allotted portions. As shown, the allocations used to construct block device 244 are selected from among heterogenous memory components (SLC and QLC memory components). In some embodiments, block device manager 113 can match the media types of selected allocations to the needs of the block device 244, as indicated by host system 120. Table 1 shows the implementation of block device 244 by block device manager 113, which is also illustrated in FIG. 2.

TABLE 1
Block Device 244 (FIG. 2)

| Allocation | Memory Device | Memory Component |
|---|---|---|
| 1 | 208 | 214 |
| 2 | 220 | 224 |
| 3 | 232 | 236 |
| 4 | 220 | 226 |
| 5 | 232 | 238 |
| 6 | 208 | 216 |

Block device manager 113 then generates and provides, to memory subsystem management stack 125, hierarchical addresses to be used to access the multiple memory components implementing the block device 244. For example, block device manager 113 provides memory subsystem management stack 125 hierarchical addresses of the media assigned to the block device 244. The hierarchy includes the memory device, memory component (with associated geometry information) and logical blocks, chunks, or pages within the memory component 112.

In some embodiments, along with the request to construct the block device, block device manager 113 receives an indication from host system 120 of needs for the block device. Such needs can include capacity, performance, endurance, or power consumption. Alternatively, host system 120 can indicate such needs in terms of media types. In some embodiments, block device manager 113 receives indications of two or more such needs and an amount of storage attributed to each need. In response, block device manager 113, when selecting the multiple memory devices and the multiple memory components, matches the needs for the block device with memory devices and components of corresponding media types. For example, the request may indicate that half of the block device is to be high-performance/low-latency storage while the other half is to be high-capacity storage. In response, block device manager 113 can select SLC media to fulfill the high-performance/low-latency storage needs and QLC media to fulfill the high-capacity storage needs. The host system 120 can also request a thin-provisioned block device (e.g., allocate only 50% capacity at first, then expand later, on demand). The host system 120 can also request the block device manager 113 to shrink allocated capacity (e.g., de-allocate 50% capacity when not being used).

FIG. 3 illustrates on-demand modification of a block device configuration, according to some embodiments. The figure illustrates a reconfiguration of the allocation from memory subsystem 110 to block device 244 as illustrated in FIG. 2 and described in Table 1. Block device manager 113 initially constructed block device 244 by selecting and aggregating six memory components, 214, 224, 236, 226, 238, and 216 (allocations 1, 2, 3, 4, 5, and 6, respectively), of memory devices 208, 220, and 232 in response to a host-requested geometry. As shown in FIG. 3, block device manager 113 modified the block device allocation to migrate allocations 2-5, remove allocation 6, and add allocations 7 and 8. This reconfigured allocation is illustrated as block device 394, containing an aggregate of seven allocations (i.e., replacement and expansion of capacity). Table 2 shows the implementation of block device 394 by block device manager 113, which is also illustrated in FIG. 3. As illustrated and described, block device manager 113 implements block device 394 with memory components 214, 212, 240, 242, 218, 226, and 238 to host a geometry consisting of allocations 1, 2, 3, 4, 5, 7, and, 8, respectively.

TABLE 2
Block Device 394 (FIG. 3)

| Reconfigured Allocation | Memory Device | Memory Component |
|---|---|---|
| 1 | 208 | 214 |
| 2 | 208 | 212 |
| 3 | 232 | 240 |
| 4 | 232 | 242 |
| 5 | 208 | 218 |
| 7 | 220 | 226 |
| 8 | 232 | 238 |

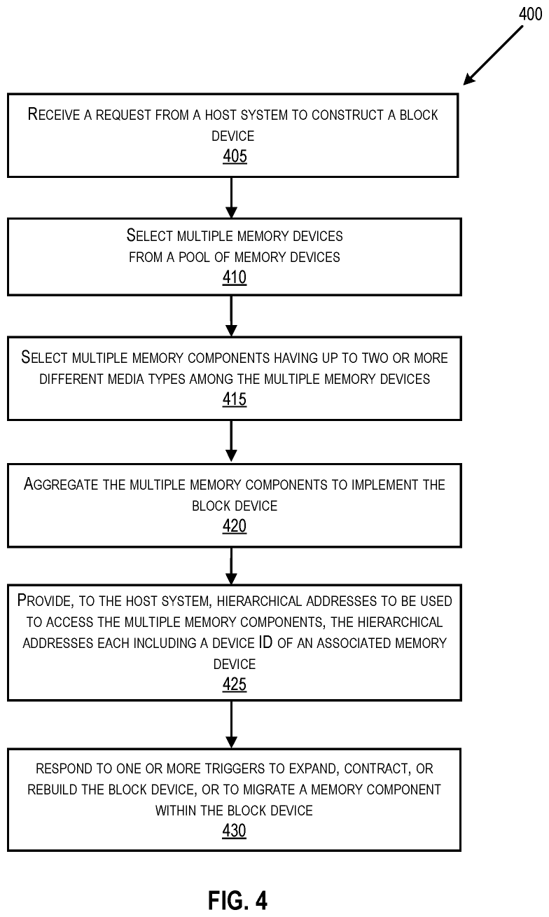

In some embodiments, block device manager 113 can receive one or more triggers calling for dynamically modifying a block device. In such embodiments, block device manager 113 can respond by reconfiguring the block device. For example, host system 120 can issue a request that triggers block device manager 113 to expand the block device. In some embodiments, block device manager 113 responds by selecting an additional memory component (or portion thereof) from among one of the memory devices already implementing the block device, one of the memory devices of the pooled memory devices, or a memory device being added to the pool of memory devices, and aggregating the additional memory component with the previously selected memory components to implement the expanded block device. Examples of such expansion of the block device include newly-added allotment 7 in memory component 226 of memory device 220 and newly-added allotment 8 in memory component 238 of memory device 232. A method for constructing a block device 244 is described further with reference to FIG. 4 below.

By supporting on-demand expansion of the block device, disclosed embodiments allow the host system 120 to increase the capacity of a block device or replace deallocated allotments if needed.

In some embodiments, host system 120 issues a request that triggers block device manager 113 to retire, expire, or deallocate a portion or an assigned allotment of a block device, or to otherwise contract the block device. The removal of allotment 6 in reconfigured block device 394 is an example of such a deallocation. Here, as shown in FIG. 3 and described in Table 2, block device manager 113 has deallocated the storage assigned to allocation 6.

By allowing on-demand contraction of the block device, disclosed embodiments enable the removal/replacement of failing or poorly performing memory devices. Deallocating unneeded memory components can also make the deallocated storage capacity available to the host system 120 for another purpose.

In some embodiments, host system 120 issues a request that triggers block device manager 113 to migrate a part of a block device from a first memory component to a second memory component of the same media type on the same memory device. Such a need can arise for a variety of reasons, such as a need to place data differently to allow for greater parallelism in accessing data, to move data from a failing memory component, changes in one or more of performance, capacity, and power consumption needs of the host system, etc. Block device manager 113 responds by selecting another memory component to which to migrate the allotment and copying the data from the previously selected memory component to the newly selected memory component. The newly selected memory component can be indicated as part of a request from host system 120. An example of a migration within the same memory device is illustrated as the migration of allocation 3 from memory component 236 of memory device 232 to same-typed memory component 240 in the same memory device 232.

In some embodiments, a need arises to migrate an allotment to another memory component of the same media type but in a different memory device. For example, the failure of a memory device or component can trigger the migration of one or more allotments. Block device manager 113 can automatically select the memory component to which to migrate the allotment or a target memory component can be indicated as part of a request from host system 120. An example of such a migration is illustrated as the migration of allotment 2 from memory component 224 of memory device 220 to same-typed memory component 212 of memory device 208.

In some embodiments, block device manager 113 receives an indication from a first memory device that the first memory device, or a memory component within the first memory device, has reached an endurance level threshold. The endurance level threshold, in some embodiments, is a predetermined threshold or a programmable threshold. In other embodiments, block device manager 113 can receive the indication from host system 120. In some embodiments, the indication automatically triggers selection of a second memory device and migration of a portion of the block device to the second memory device.

In some embodiments, host system 120 requests reconfiguration of a block device in response to a change in performance, capacity, or power consumption needs. For example, an application that no longer needs (or needs less) high-performance memory can instruct block device manager 113 to migrate part of the block device to a low-performance media type. Likewise, an application may need more capacity, or may need to reduce power consumption. In such embodiments, block device manager 113 can migrate a portion of the block device from one memory component (of multiple memory components) to another memory component of another memory device (of a pool of memory devices). In one embodiment, the second memory component is of a different media type than the first memory component. For example, the media type of the second memory component could be better suited than the first memory component to meet one or more of performance, capacity, and power consumption needs of the host system. Following the example above, the different media type can be a lower-cost, lower-power media type. Block device manager 113 can similarly migrate data from a low-performance media type to a high-performance media type. Disclosed embodiments allow such power and cost optimizations. An example of migrating an allocation from a high-performance memory component to a lower-performance, less costly memory component is illustrated as the migration of allotment 5 from memory component 238 of SLC memory device 232 to memory component 218 of QLC memory device 208.

An example of migrating an allotment from a low-performance, low-cost media type to a higher-performing, higher-cost media type is illustrated as the migration of allotment 4 from QLC memory component 226 of memory device 220 to SLC memory component 242 of memory device 232.

For another example, in some embodiments, one or more memory devices and memory components are initially allocated as part of a block device. Some embodiments respond to a trigger to rebuild the block device due to changing needs of a host system (e.g., a newly requested geometry, to implement tiering, or to implement caching). In some such embodiments, a new block device is constructed by selecting a new group of memory devices from the pool of memory devices, selecting a new group of memory components including up to two or more different media types from among the new group of memory devices, and aggregating the new group of memory components to build the new block device. It should be noted that a memory device can be added to or removed from the pool of memory devices, thereby creating a new pool of memory devices, before or after constructing the block device. For example, some embodiments respond to a trigger to rebuild a block device by first adding or removing zero or more memory devices to the pooled memory devices.

Disclosed embodiments can also gain advantages in redundancy, fault tolerance, and performance by constructing a block device that operates as a Redundant Array of Independent Memory Components (RAIMC). As used herein, RAIMC combines multiple physical memory components across memory devices in the memory sub-system into one logical unit (in contrast to a Redundant Array of Independent Disks (RAID), which uses multiple disks to create the logical unit). More particularly, in some embodiments, a processing device (i.e. block device manager) selects multiple memory components from subsystems/devices to be used as a RAIMC. The processing device provides, to a host system, a hierarchical address for accessing a first memory component. The hierarchical address includes a host ID of an associated host system and a device ID of an associated memory device. The processing device stripes and/or duplicates the data accesses addressed to the first memory component across the multiple memory components. In some embodiments, the processing device also stores, for each data element, an error correction value (e.g., a parity value can be stored in a third memory component indicating a data error when an exclusive-OR (XOR) of two corresponding elements of duplicated first and second memory components is other than zero.) In some embodiments, the RAIMC is used with erasure coding algorithms, which involve a total of n memory components of which m components store data and k components store parity information, such that n=m+k. Disclosed embodiments allow construction of the RAIMC using heterogeneous memory components, be they within a same memory device, memory subsystem, or host system, and/or in different memory devices, memory subsystems, or host systems.

FIG. 4 is a flow diagram of an example method to construct a heterogeneous block device, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the block device manager 113 of FIG. 1. Although shown in a particular sequence or order, unless otherwise specified, the order of the processes can be modified. Thus, the illustrated embodiments should be understood only as examples, and the illustrated processes can be performed in a different order. Some processes can be performed in parallel. Additionally, one or more processes can be omitted in various embodiments. Thus, not all processes are required in every embodiment. Other process flows are possible.

At operation 405, the processing device receives a request to construct a block device. For example, block device manager 113 receives the block device request from the operating system, an application, or another process running within host system 120. In one embodiment, the request indicates needs of the block device. In one embodiment, the needs include two or more of capacity, performance, endurance, or power consumption. In one embodiment, the request specifies a requested geometry for the block device (e.g., number of memory devices, parallel units/groups for memory components within devices, etc.).

At operation 410, the processing device selects multiple memory devices from among a pool of memory devices. For example, block device manager 113 can maintain a data structure listing available memory component resources with associated geometry in a pool of memory devices.

In one embodiment, such an availability data structure lists available memory devices, available memory components therein, available media types, storage ranges yet to be allocated, etc. In some embodiments, the availability data structure also includes characteristics of available storage space, for example, the largest available contiguous block, the smallest available block, geometry (parallel units/groups), etc. In one embodiment, the availability data structure is used to prepare an on-demand report of allotted storage space and memory device statistics. In some embodiments, the availability data structure is maintained by the block device manager 113 performing method 400. With reference to the availability data structure, for example, block device manager 113 selects multiple memory devices from among a list (e.g., a pool) of memory devices 208, 220, and 232. In some embodiments, block device manager 113 applies a selection strategy that balances system-wide storage utilization by attempting to evenly spread allotted storage spaces across multiple memory devices and components. In one example, when the request includes a requested geometry, block device manager 113 selects the multiple memory devices to match the request.

At operation 415, the processing device selects multiple memory components having up to two or more (i.e., one, two, three, or more) different media types from among the multiple memory devices. For example, as mentioned above, block device manager 113 can maintain an availability data structure and select memory components according to the request. In an example, block device manager 113 accesses the availability data structure and selects multiple memory components, 214, 224, 236, 226, 238, and 216, having up to two or more (i.e., one, two, three, or more) different media types from among the multiple memory devices. In this example, the selected memory components have two different media types: SLC and QLC. In some embodiments, block device manager 113 selects memory components with homogeneous media types (e.g., all SLC).

At operation 420, the processing device aggregates the multiple memory components to implement the block device. For example, block device manager 113 identifies hierarchical addresses to be used to access the multiple allocated memory components. Such hierarchical addresses each include a device ID of an associated memory device.

In an embodiment, block device manager 113 aggregates the multiple allocated memory components and constructs a geometry data structure detailing the geometry of the block device 244. For example, such a geometry data structure can include logical block addresses, parallel units/groups and address formats of the memory component allocations making up the block device. Additionally, such a geometry data structure can specify write data requirements, such as the minimum write data size. A geometry data structure can also indicate performance-related metrics, such as typical and maximum time for reads, writes, and resets.

In one embodiment, block device manager 113 maintains a log, or history data structure indicating past allocations, including allocations made for past requests.

Block device manager 113 updates such a data structure when new allocations are to be provided in response to the request. In an embodiment, the history data structure can be used to rebuild a block device in the event of a fault or failure (e.g., memory component failure or memory device failure).

At operation 425, the processing device provides, to the memory subsystem management stack, hierarchical addresses to be used to access the multiple memory components. For example, block device manager 113 provides the geometry data structure created at operation 420 to memory subsystem management stack 125. Hierarchical addresses provided to memory subsystem management stack 125 each include a device ID of an associated memory device. The hierarchical addresses can also include a geometry and other addressing that may be required for individual memory components within a memory device.

In some embodiments, the hierarchical addresses include fields that identify several layers of address hierarchy associated with each memory component, including:
Device ID: identifies an associated memory device.
Group: Collection of parallel units (PUs), each on a different transfer bus or channel on the device.
Parallel Unit (PU): Collection of individual memory components that share the same transfer bus or channel on the device.
Logical block: Minimum addressable unit for reads and writes.
Chunk: Collection of logical blocks. Can also be the minimum addressable unit for resets (erases).

In one embodiment, memory subsystem management stack 125 maintains, for future use, an allocation data structure containing logical addresses allocated to one or more block devices. In another embodiment, each of the memory devices in the computing environment 100 maintains an allocation data structure listing details about past allotments. Such an allocation data structure can be used to rebuild block device allocations in case of a fault (e.g., memory component or device failure). Such an allocation data structure can also be used to generate an on-demand report of system-wide storage allocations.

At operation 430, the processing device responds to one or more triggers to expand, contract, or rebuild the block device, or to migrate a memory component within the block device. In some embodiments, the processing device can add a new memory device or a new memory component to the block device. For example, block device manager 113 can become aware of the occurrence of any of the following triggers to dynamically modify the block device: 1) Failure of a component (e.g., memory component or memory device failure), 2) Changing endurance (i.e., a memory device nears an endurance level threshold), 3) Changing performance needs (e.g., increased performance requirements or decreased performance requirements of the host system), 4) Changing capacity needs (e.g., increased capacity requirements or decreased capacity requirements of the host system), 5) Changing power consumption needs (e.g., an increased power budget may call for more or faster media to be added; a decreased power budget may call for deallocating some storage media or migrating a portion of the block device to a lower-performance, lower-power media type), and 6) Other changing needs (e.g., a newly requested geometry, a need to implement tiering, or a need to implement caching). Disclosed embodiments respond to such a trigger by dynamically rebuilding or modifying the block device.

For example, in some embodiments, when host system 120 needs higher performance storage, it migrates part of the block device to a higher-performing media type. In such an embodiment, block device manager 113 migrates a portion of the block device from a memory component of a first of the multiple memory devices to a memory component on a second memory device having a different, higher-performance media type. The first and second memory devices can be associated with either the same host system or different host systems. An example of migrating an allocation from a low-performance, low-cost media type to a high-performing media type is illustrated as the migration of allocation 4 from QLC memory component 226 of memory device 220 to SLC memory component 242 of memory device 232 as illustrated in FIGS. 2-3.

By allowing on-demand migration of allocations among heterogeneous memory components, including heterogeneous non-volatile memory components, some disclosed embodiments improve performance by enabling dynamic caching allocations.

For another example, in some embodiments, one or more memory devices and memory components are initially allocated as part of a block device. Some embodiments respond to a trigger indicating the block device is to be rebuilt due to changing needs of a host system (e.g., a newly requested geometry, to implement tiering, or to implement caching). In some such embodiments, a new block device is constructed by selecting a new group of memory devices from the pool of memory devices, selecting a new group of memory components including up to two or more different media types from among the new group of memory devices, and aggregating the new group of memory components to build the new block device.

Once constructed, hierarchical addresses used to access the memory components of the block device are provided to the host system. Here, the hierarchical address can contain a host ID associated with each memory component, as well as identifiers for a device ID, a group, a parallel unit, a logical block, and a chunk, as described above.

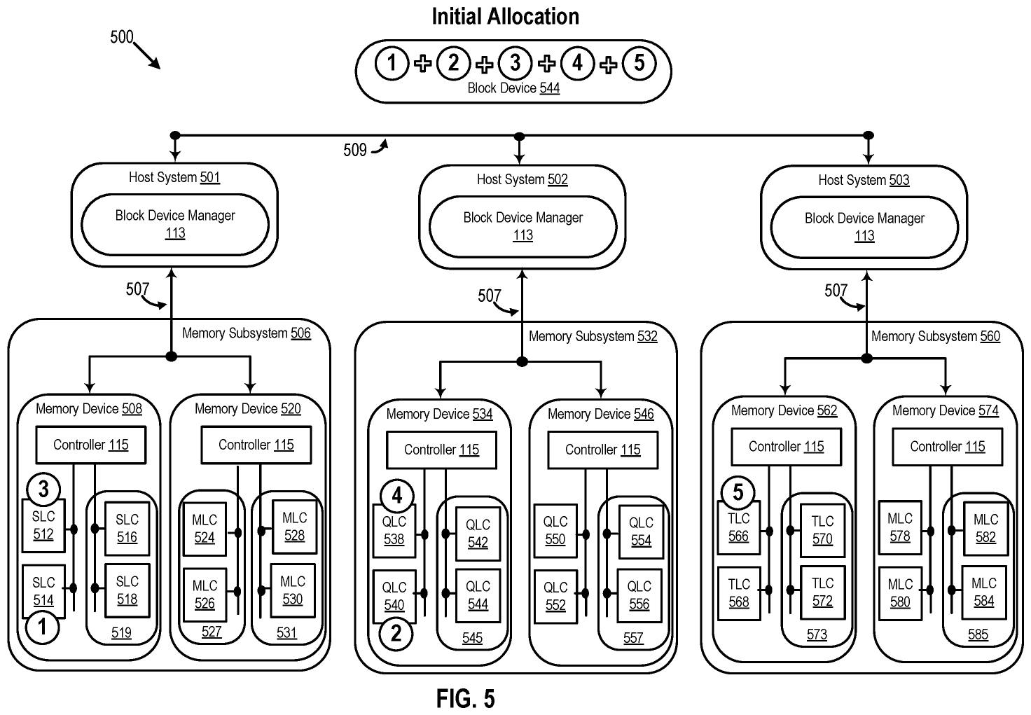

FIG. 5 illustrates another initial allocation of multiple heterogeneous memory components to host a block device, according to some embodiments. As shown, computing system 500 includes a pool of host systems, 501, 502, and 503, each of which includes block device manager 113. Host systems 501, 502, and 503 are examples of host system 120, described above. It should be noted that, in operation, host systems can be added to or removed from the pool of host systems. For example, a block device can be expanding by adding a memory component selected from an added memory device in another host system being added to the pool of host systems.

Host system bus 509 allows communications among the pool of host systems, 501, 502, and 503. For example, host system 501 can maintain a list or other data structure indicating amounts of available media types within memory devices 508 and 520 and share that data with host systems 502 and 503. Similarly, host systems 502 and 503 can maintain and share similar data structures for their respective underlying memory subsystems 532 and 560. In one embodiment, a host system uses host system bus 509 to request an allocation of media from a memory subsystem managed by another host system within the pool. In some embodiments, host system bus 509 is an Ethernet, PCIe, Infiiband, or another host network inter-connect bus. In other embodiments, hosts 501-503 communicate via an NVMeOF (NVMe Over Fabrics) protocol connection over the bus.

Memory subsystem 506 is associated with host system 501 and includes a pool of memory devices 508 and 520. It should be noted that, in operation, memory devices can be added to or removed from the pool of memory devices, and host systems can be added to or removed from the pool of host systems. Memory device 508 includes controller 115 and four SLC memory components, 512, 514, 516, and 518. Memory device 520 includes controller 115 and four MLC memory components 524, 526, 528, and 530. Controllers 115 of memory devices 508 and 520 are examples of controller 115, discussed above. In some embodiments, as here, memory components 512, 514, 516, 518, 524, 526, 528, and 530, can be abstracted into groups of parallel units by channel. For example, different memory components can be coupled to the controller via different channels, enhancing parallelism and throughput. Such groups provide another layer of addressing. SLC memory components 516 and 518 are a part of parallel unit 519. MLC memory components 528 and 530 are a part of parallel unit 531. Likewise, MLC memory components 524 and 526 are part of parallel unit 527. Parallel units 531 and 527 are groups and each belong to separate channels or transfer buses.

Memory subsystem 532 is associated with host system 502 and includes a pool of memory devices 534 and 546. Memory device 534 contains a controller 115 and four QLC memory components, 538, 540, 542, and 544. Memory components 542 and 544 are part of parallel unit 545. Memory device 546 contains controller 115 and four QLC memory components: 550, 552, 554, and 556. QLC Memory components 554 and 556 are part of parallel unit 557.

Memory subsystem 560 is associated with host system 503 and includes a pool of memory devices 562 and 574. Memory device 562 contains controller 115 and four TLC memory components, 566, 568, 570, and 572. TLC Memory components 570 and 572 are part of parallel unit 573. Memory device 574 contains controller 115 and four MLC memory components 578, 580, 582, and 584. MLC Memory components 582 and 584 are part of parallel unit 585.

Each of host systems 501, 502, and 503 can use a memory subsystem bus 507 to communicate with its associated memory subsystem 506, 532, and 560, respectively. In some embodiments, memory subsystem bus 507 allows each of the host systems to communicate with memory devices and memory components in its associated memory subsystem. In some embodiments, memory subsystem bus 507 is a Peripheral Component Interface-express (PCIe) bus, and data packets communicated on the bus adhere to a Non-Volatile Memory-express (NVMe) protocol. This bus can be other types such as Gen-Z, CXL (Computer Express Link), CCIX (Cache Coherent Interconnect for Accelerators), DDR (Double Data Rate), etc.

Here, computing system 500 is shown including SLC, MLC, TLC, and QLC memory devices. Other embodiments include memory components having any of various media types, including the illustrated media types and/or a cross-point array of non-volatile memory cells.

In operation, focusing on host system 501 as an example, block device manager 113 receives, from processor(s) 130 (not shown here, but described above with respect to FIG. 1), a request to construct a block device 544. For example, block device manager 113 constructs the block device 544 by allotting physical units, dice, and/or LUNs. Inc some embodiments, the memory devices 508, 520, 534, 546, 562, and 574 make their internal storage resources visible to the host systems. In so doing, memory devices 508, 520, 534, 546, 562, and 574 can be said to form a pool of memory devices that are coupled to the pool of host systems 501, 502, and 503. In some embodiments, host system 501 can discover the geometry of memory components within memory devices 508, 520, 534, 546, 562, and 574, for example by issuing a geometry command to the memory devices. As described above, host system 501 can then specify a requested geometry along with (or in addition to) the request to construct the block device.

In one embodiment, block device manager 113 selects multiple host systems (including host systems 501, 502, and 503) from among a pool of host systems, and multiple memory devices (including memory devices 508, 534, and 562) from the selected host systems, to implement the block device. From among the selected memory devices, block device manager 113 further selects multiple memory components to implement block device 544. As shown, block device manager 113 allocates portions of the memory devices, e.g., assigns physical units (PUs), dice, and/or logical unit numbers (LUNs) of five memory components to implement block device 544. As shown, the allocations used to construct block device 544 are selected from among heterogenous memory components (memory components of varied media types: SLC, MLC, TLC, and QLC). In some embodiments, block device manager 113 can match the media types of selected allocations to the needs of the block device 544, as indicated by host system 501. Table 3 describes the original implementation of block device 544 by block device manager 113, as illustrated in FIG. 5.

TABLE 3
Block Device 544 (FIG. 5)

| | Memory | Memory | Memory |
|---|---|---|---|
| Allotment | Subsystem | Device | Component |
| 1 | 506 | 508 | 514 |
| 2 | 532 | 534 | 540 |
| 3 | 506 | 508 | 512 |
| 4 | 532 | 534 | 538 |
| 5 | 560 | 562 | 566 |

Block device manager 113 then generates and provides, to host system 501, hierarchical addresses to be used to access the multiple memory components implementing the block device 544. For example, block device manager 113 provides memory subsystem management stack 125 hierarchical addresses of the media assigned to the block device 544.

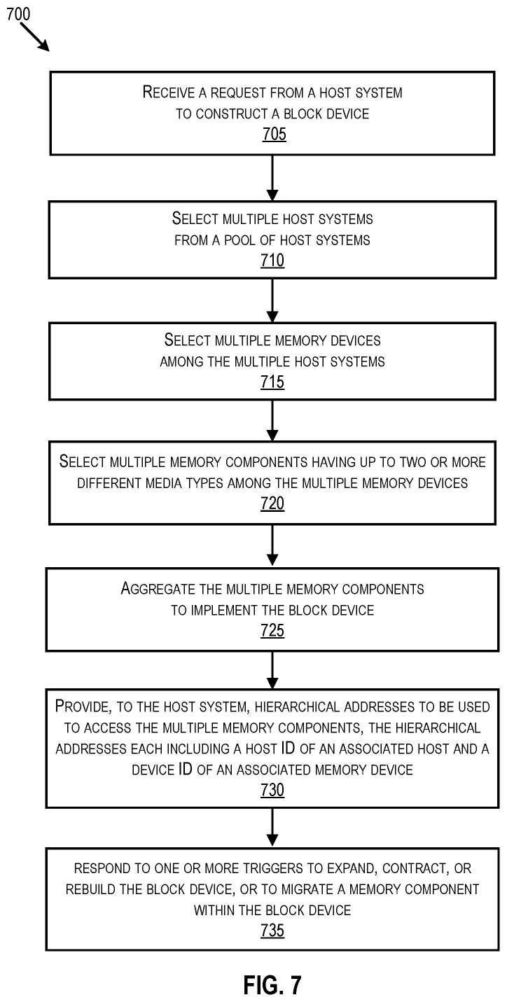

In some embodiments, along with (or in addition to) the request to construct the block device, block device manager 113 receives an indication from host system 501 of needs for the block device. Such needs can include capacity, performance, endurance, or power consumption. Alternatively, host system 501 can indicate such needs in terms of media types. In some embodiments, block device manager 113 receives indications of up to two or more (i.e., one, two, three, or more) such needs and an amount of storage attributed to each need. In response, block device manager 113, when selecting the multiple host systems, multiple memory devices, and multiple memory components, matches the needs for the block device with media types. For example, the request may indicate that half of the block device is to be high-performance/low-latency storage while the other half is to be high-capacity storage. In response, block device manager 113 can select SLC media to fulfill the high-performance/low-latency storage needs and QLC media to fulfill the high-capacity storage needs. A method for constructing a block device 544 is described further with reference to FIG. 7 below.

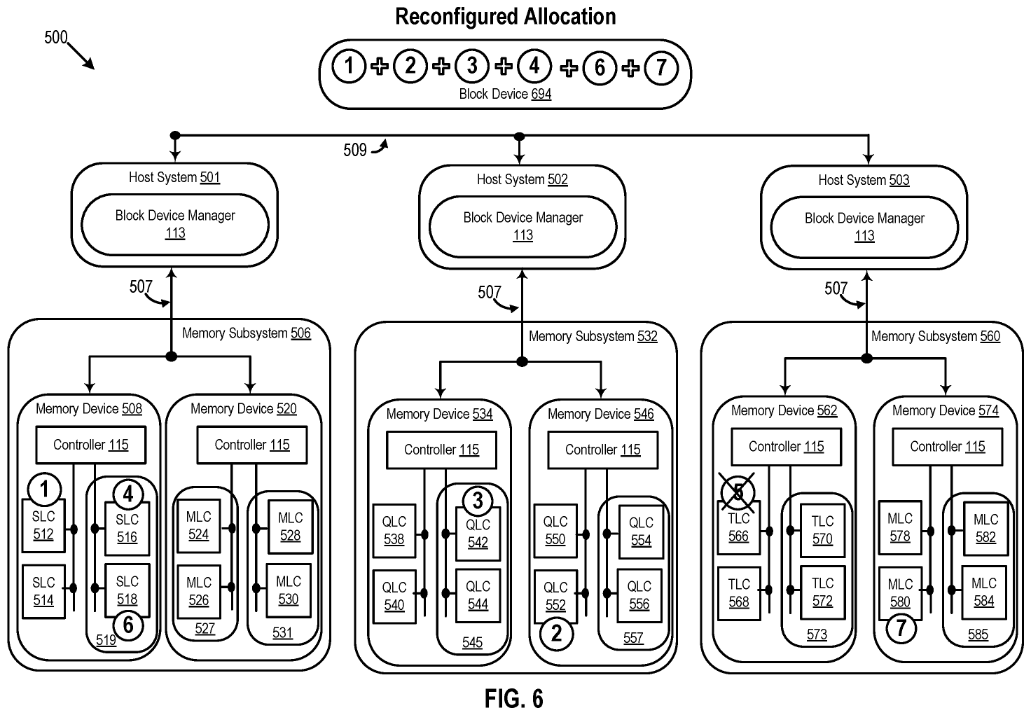

FIG. 6 illustrates a modified block device configuration in accordance with some embodiments of the present disclosure. The figure illustrates a reconfiguration of the allocations of memory subsystems 506, 532, and 560 as illustrated in FIG. 5 and described in Table 3.

Block device manager 113 initially constructed block device 544 by selecting and aggregating five memory components, 514, 540, 512, 538, and 566 (allocations 1, 2, 3, 4, and 5, respectively), of memory devices 508, 534, and 562, in response to a host-requested geometry. As shown in FIG. 6, block device manager 113 modified the block device allocation to migrate allocations 1-4, remove allocation 5, and add allocations 6 and 7. This reconfigured allocation is illustrated as block device 694, containing an aggregate of six allocations. Table 4 shows the implementation of block device 694 by block device manager 113, as illustrated in FIG. 6. As illustrated and described, block device manager 113 implements block device 694 with memory components 512, 552, 542, 516, 518, and 580 to host a geometry consisting of allocations 1, 2, 3, 4, 6, and 7, respectively.

TABLE 4
Block Device 694 (FIG. 6)

| | Memory | Memory | Media |
|---|---|---|---|
| Allocation | Subsystem | Device | Component |
| 1 | 506 | 508 | 512 |
| 2 | 532 | 546 | 552 |
| 3 | 532 | 534 | 542 |
| 4 | 506 | 508 | 516 |
| 6 | 506 | 508 | 518 |
| 7 | 560 | 574 | 580 |

In some embodiments, block device manager 113 reconfigures a block device in response to a request from a host system. For example, host system 501 can issue a request that triggers block device manager 113 to expand the block device. In some embodiments, block device manager 113 responds by selecting an additional memory component (or portion thereof) from among the pooled memory devices, or from another memory device of the pool of memory devices, or from an additional memory device being added to the pool of memory devices, or from an additional host system being added to the pool of host systems, and aggregating the additional memory component with the previously selected memory components to implement the expanded block device. Examples of such expansion of the block device include newly-added allotment 6 in memory component 518 of memory device 508 and newly-added allotment 7 in memory component 580 of memory device 574.

For example, in some embodiments, block device manager 113 can expand the block device by dynamically selecting an additional memory device containing additional memory components from among the multiple memory devices and aggregating the additional memory components with the multiple memory components already implementing the block device.

By supporting on-demand expansion of the block device, disclosed embodiments allow the host system 501 to increase the capacity of a block device or replace deallocated allotments if needed.

In some embodiments, host system 501 issues a request that triggers block device manager 113 to retire, expire, or deallocate a portion of an allotment, or otherwise contract a block device. The removal of allotment 5 in reconfigured block device 694 is an example of such a deallocation. Here, as shown in FIG. 6 and described in Table 4, block device manager 113 has deallocated the storage assigned to allocation 5.

By allowing on-demand contraction of the block device, disclosed embodiments enable the removal/replacement of failing or poorly performing memory devices. Deallocating unneeded memory components can also make the deallocated storage capacity available to the host system 501 (and to host systems 502 and 503) for another purpose.

In some embodiments, host system 501 issues a request that triggers block device manager 113 to migrate a part of a block device from a first memory component to a second memory component of the same media type on the same memory device. Such a need can arise for a variety of reasons, such as a need to place data differently to allow for greater parallelism in accessing data, to move data from a failing memory component, etc. Block device manager 113 responds by selecting another memory component to which to migrate the allotment and copying the data from the previously selected memory component to the newly selected memory component. The newly selected memory component can be indicated as part of a request from host system 501. An example of a migration within the same memory device is illustrated as the migration of allocation 1 from memory component 514 of memory device 508 to same-typed memory component 512 in the same memory device 508.

In some embodiments, a need arises to migrate an allotment to another memory component of the same media type, but in a different memory device. For example, the failure of a memory device can trigger the migration of one or more allotments. Block device manager 113 can select the memory component to which to migrate the allotment or a target memory component can be indicated as part of a request from host system 501. An example of such a migration is illustrated as the migration of allotment 2 from QLC memory component 540 of memory device 534 to same-typed, QLC memory component 552 in memory device 546.

In some embodiments, block device manager 113 receives an indication from a first memory device that the first memory device, or a memory component within the first memory device, has reached an endurance level threshold. In other embodiments, block device manager 113 receives the indication from host system 120. The indication triggers selection of a second memory device and migration of a portion of the block device to the second memory device.

As described above, in some embodiments, host system 501 dynamically reconfigures a block device in response to any of several triggers. By way of the reconfiguring, the block device can be expanded, contracted, rebuilt, thin-provisioned, duplicated, and migrated. An example of migrating an allotment from a low-performance, low-cost media type to a higher-performing, higher-cost media type is illustrated as the migration of allotment 4 from QLC memory component 538 of memory device 534 to SLC memory component 516 of memory device 508.

In some embodiments, host system 501 no longer needs (or needs less) high-performance storage and migrates part of the block device to a less costly media type. In such embodiments, block device manager 113 migrates a portion of the block device from a first memory component of a first of the multiple memory devices to a second memory component on a second memory device, the second memory component having a different media type than that of the first memory component. An example of migrating an allocation from a high-performance memory component to a less-costly memory component is illustrated as the migration of allocation 3 from SLC memory component 512 of memory device 508 of memory subsystem 506 to QLC memory component 542 of memory device 534 of memory subsystem 532.

In some embodiments, host system 501 needs higher performance storage and migrates part of the block device to a higher-performing media type. In such an embodiment, block device manager 113 migrates a portion of the block device from a first memory component of a first of the multiple memory devices to a second memory component on a second memory device, the second memory component having a different, higher-performance media type. The first and second memory devices may be associated with either the same host system, or different host systems. An example of migrating an allocation from a low-performance, low-cost media type to high-performing media type is illustrated as the migration of allocation 4 from QLC memory component 538 of memory device 534 of memory subsystem 532 to SLC memory component 516 of memory device 508 of memory subsystem 506.

By allowing on-demand migration of allocations among heterogeneous memory components, some disclosed embodiments improve performance by enabling dynamic caching allocations.

FIG. 7 is a flow diagram of an example method to construct a heterogeneous block device, in accordance with some embodiments of the present disclosure. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by the block device manager 113 of FIG. 1. Although shown in a particular sequence or order, unless otherwise specified, the order of the processes can be modified. Thus, the illustrated embodiments should be understood only as examples, and the illustrated processes can be performed in a different order. Some processes can be performed in parallel. Additionally, one or more processes can be omitted in various embodiments. Thus, not all processes are required in every embodiment. Other process flows are possible.

At operation 705, the processing device receives a request from a host system to construct a block device. For example, block device manager 113 receives the block device request from the operating system, an application, or another process running within host system 501. In one embodiment, the request indicates needs of the block device. In one embodiment, the needs include two or more of capacity, performance, endurance, or power consumption. In one embodiment, the request specifies a requested geometry for the block device.

At operation 710, the processing device selects multiple host systems from among a pool of host systems. For example, block device manager 113 can maintain a data structure listing available resources in a pool of host systems. The creation, maintenance, and use of such an availability data structure is similar to that of the availability data structure described above with respect to operation 410. The availability structure used in method 700, however, also includes availability information about multiple host systems.

In one embodiment, the availability data structure is maintained and updated by the heterogeneous block device managers 113 in the host system performing method 700. In some embodiments, the availability data structure is maintained and updated by one or more other redundant heterogeneous block device managers 113 in the system 500. For example, in response to allocating, modifying, or deallocating a block device 544, the block device manager 113 of host system 501 can transmit an update to the availability data structure reflecting available memory resources in the system 500 to heterogeneous block device managers 113 in host systems 502 and 503, enabling each block device manager 113 to update a local copy of the availability data structure. Such redundant availability data structures can be used to reconstruct past allotments, for example in the case of a fault (e.g., failure of a host system or device or component).

In some embodiments, each of the hosts or memory devices in the system maintains a local availability data structure relating to the memory components in its domain. Such a local availability data structure is queried by the heterogeneous block device managers 113 performing method 700 before performing operation 710. That way, block device manager 113 will have up-to-date, accurate knowledge of system-wide allotments. Such up-to-date knowledge will also reflect allocations created or deleted by other heterogeneous block device managers 113.

As described above, such an availability data structure lists available host systems, memory devices, and memory components, as well as available media types, storage ranges yet to be allocated, etc. With reference to such an availability data structure, for example, block device manager 113 selects multiple host systems from a list (e.g., a pool) of host systems 501, 502, and 503. In one example, when the request includes a requested geometry, block device manager 113 selects the multiple host systems, memory devices, and memory components to match the request. In one embodiment, block device manager 113 gives priority to memory devices/components directly coupled/local to the host system originating the request and utilizes memory devices/components coupled to other host systems in the pool when the request cannot be fulfilled locally (e.g., due to lack of availability in the corresponding media type). In some embodiments, block device manager 113, when performing operation 710, applies a selection strategy like the selection strategy described above with respect to operation 410.

At operation 715, the processing device selects multiple memory devices from among the multiple host systems. For example, as with operation 710, block device manager 113, with reference to the availability data structure, selects multiple memory devices from among a pool of memory devices 508, 520, 534, 546, 562, and 574. In one example, when the request includes a requested geometry, block device manager 113 selects the multiple hosts and multiple memory devices to match the request.

In one embodiment, the request indicates needs of the block device (e.g., two or more of capacity, performance, endurance, or power consumption). When the request indicates the needs of the block device, block device manager 113 selects available host systems, memory devices, and memory components to implement the block device. In one example, when the request indicates a need for a high-performance portion of the block device, block device manager 113 matches that need by selecting a SLC memory component. In another example, when the request indicates a need for a low-cost portion of the block device, the block device manager 113 matches that need by selecting a QLC memory component.

At operation 720, the processing device selects multiple memory components having up to two or more (i.e., one, two, three or more) media types from among the multiple memory devices. For example, as mentioned above, block device manager 113 can maintain an availability data structure. In one example, with reference to the availability data structure, block device manager 113 selects multiple memory components, 514, 540, 512, 538, and 566, having up to two or more (i.e., one, two, three, or more) different media types, from among the multiple memory devices selected at operation 715. In this example, the selected memory components have three different/heterogenous media types: SLC, QLC, and TLC. In some embodiments, block device manager 113 can select memory components having homogenous media types.

At operation 725, the processing device aggregates the multiple memory components to implement the block device. For example, block device manager 113 identifies hierarchical addresses to be used to access the multiple allocated memory components. Such hierarchical addresses each include host ID of an associated host system and a device ID of an associated memory device.

In an embodiment, block device manager 113 aggregates the multiple allocated memory components and constructs a geometry data structure (like the one described above with respect to operation 420) detailing the geometry of the block device 544. For example, such a geometry data structure can include logical block addresses and address formats of the allocations making up the block device. Additionally, such a geometry data structure can specify write data requirements, such as the minimum write data size. A geometry data structure can also indicate performance-related metrics, such as typical and maximum times for reads, writes, and resets.

In one embodiment, block device manager 113 maintains a log, or history data structure indicating past allocations, including allocations made for past requests. Block device manager 113 updates such a data structure when new allocations are to be provided in response to the request. In an embodiment, the history data structure can be used to rebuild a block device in the event of a fault or failure (e.g., host, device, or component failure).

At operation 730, the processing device provides, to the host system, hierarchical addresses to be used to access the multiple memory components. For example, block device manager 113 provides the geometry data structure created at operation 725 to host system 120. Hierarchical addresses provided to host system 120 each include a host ID of an associated host system and a device ID of an associated memory device. As described above, the hierarchical address can also describe a device ID, a group, a parallel unit, a logical block, and a chunk.

At operation 735, similar to operation 430, the processing device responds to one or more triggers to expand, contract, or rebuild the block device, or to migrate a memory component within the block device.

In one embodiment, host system 501 maintains, for future use, an allocation data structure containing logical addresses allocated to it. In another embodiment, each of the memory devices in the system 500 maintains an allocation data structure listing details about past allotments. Such an allocation data structure can be used to rebuild block device allocations in case of a fault (e.g., memory component fault, device fault, or host fault). Such an allocation data structure can also be used to generate an on-demand report of system-wide storage allocation. In another embodiment, one or more of host systems 502 and 503 maintain a redundant copy of the allocation data structure.

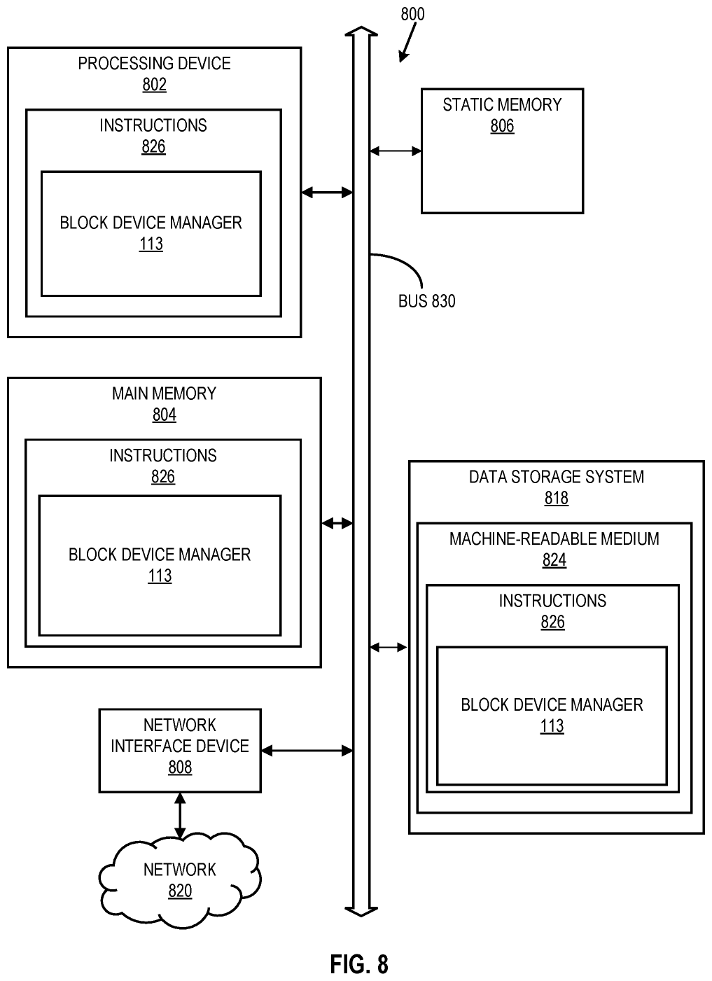

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the block device manager 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 826 for performing the operations and steps discussed herein. The computer system 800 can further include a network interface device 808 to communicate over the network 820.

The data storage system 818 can include a machine-readable storage medium 824 (also known as a computer-readable medium) on which is stored one or more sets of instructions 826 or software embodying any one or more of the methodologies or functions described herein. The instructions 826 can also reside completely, or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory subsystem 110 of FIG. 1.

In one embodiment, the instructions 826 include instructions to implement functionality corresponding to a heterogeneous block device manager component (e.g., the block device manager 113 of FIG. 1). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that can store or encode a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, can carry out the computer-implemented methods 400 and 700 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs (Erasable Programmable Read Only Memory), EEPROMs (Electrically Erasable Programmable Read Only Memory), magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
receiving, from a host system among a pool of host systems, a request to construct an allocation of memory, the pool of host systems being coupled to a pool of memory devices;
selecting a plurality of memory devices among the pool of memory devices;
selecting a plurality of memory components among the plurality of memory devices;
aggregating the plurality of memory components to implement the allocation of memory; and
providing, to the host system, hierarchical addresses to be used to access the plurality of memory components implementing the allocation of memory, the hierarchical addresses each comprising a device ID of an associated memory device and a host ID of an associated host system.

2. The method of claim 1, further comprising:
receiving an indication, from the host system, specifying needs of the allocation of memory; and
wherein selecting the plurality of memory devices and the plurality of memory components includes matching the needs of the allocation of memory with media types of the memory components, and wherein the needs of the allocation of memory include two or more of capacity, performance, endurance, or power consumption.

3. The method of claim 1, further comprising:
expanding the allocation of memory, when the one or more triggers indicate one or more of increased capacity requirements, increased performance requirements, or increased power budget, by selecting an additional memory component from among the plurality of memory devices or from another memory device of the pool of memory devices, or from an additional memory device being added to the pool of memory devices, or from an added memory device in another host system being added to the pool of host systems, and aggregating the additional memory component with the plurality of memory components already implementing the allocation of memory; and
contracting the allocation of memory, when the one or more triggers indicate one or more of decreased capacity requirements, decreased performance requirements, and decreased power budget, by selecting and deallocating either one of the plurality of memory components or one of the plurality of memory devices and any of the plurality of memory components contained therein.

4. The method of claim 1, further comprising:
migrating a first portion of the allocation of memory from a first memory component of the plurality of memory components to a second memory component on a second of the pool of memory devices, wherein the migrating is triggered by:
changes in one or more of performance, capacity, and power consumption needs of the host system,
an indication that a first memory device of the plurality of memory devices has reached an endurance level threshold, or
an indication of a failure of the first memory component.

5. The method of claim 1, further comprising:
rebuilding the allocation of memory to generate a new allocation of memory, when triggered by changing needs of the host system, by:
selecting a new plurality of host systems from the pool of host systems, the new plurality of host systems comprising a new pool of memory devices,
selecting a new plurality of memory devices from the new pool of memory devices,
selecting a new plurality of memory components comprising up to two or more different media types from among the new plurality of memory devices,
aggregating the new plurality of memory components to build a new allocation of memory, and
providing, to the host system, hierarchical addresses to be used to access the new plurality of memory components implementing the new allocation of memory, the hierarchical addresses each comprising a device ID of an associated memory device,
wherein the changing needs of the host system comprise one of a newly requested geometry, a need to implement tiering, and a need to implement caching.

6. The method of claim 1, further comprising:
selecting first, second, and third memory components from among the plurality of memory components;
using the first, second, and third memory components as a redundant array of independent memory components (RAIMC);
providing, to the host system, a hierarchical address to be used to access the first memory component, the hierarchical address comprising a host ID of an associated host system and a device ID of an associated memory device;
duplicating, to the second and third memory components, data accesses addressed to the first memory component; and
storing, for each data element of the third memory component, a parity reflecting an exclusive-OR (XOR) of corresponding elements of the first and second memory components, and wherein a value of ‘1’ of the parity indicates a data error.

7. The method of claim 1, wherein the plurality of memory components are heterogeneous, comprising different types of non-volatile memory components, including two or more of: single-level cell (SLC) NAND flash, multi-level cell (MLC) NAND flash, triple-level cell (TLC) NAND flash, and quad-level-cell (QLC) NAND flash, 3D XPoint, ReRAM, and NRAM (Nano-RAM, a resistive non-volatile random access memory (RAM)).

8. A system comprising:
a pool of host systems coupled to a pool of memory devices; and
a processing device coupled to the pool of memory devices and the pool of host systems, to:
receive, from a host system among the pool of host systems, a request to construct an allocation of memory,
select a plurality of memory devices among the pool of memory devices,
select a plurality of memory components among the plurality of memory devices,
aggregate the plurality of memory components to implement the allocation of memory, and
provide, to the host system, hierarchical addresses to be used to access the plurality of memory components implementing the allocation of memory, the hierarchical addresses each comprising a device ID of an associated memory device and a host ID of an associated host system.

9. The system of claim 8, wherein the processing device is further to:
receive an indication, from the host system, specifying needs of the allocation of memory; and
wherein selecting the plurality of memory devices and the plurality of memory components includes matching the needs of the allocation of memory with media types of the memory components, and wherein the needs of the allocation of memory include two or more of capacity, performance, endurance, or power consumption.

10. The system of claim 8, wherein the processing device is further to:
expand the allocation of memory, when the one or more triggers indicate one or more of increased capacity requirements, increased performance requirements, or increased power budget, by selecting an additional memory component from among the plurality of memory devices or from another memory device of the pool of memory devices, or from an additional memory device being added to the pool of memory devices, or from an added memory device in another host system being added to the pool of host systems, and aggregating the additional memory component with the plurality of memory components already implementing the allocation of memory; and
contract the allocation of memory, when the one or more triggers indicate one or more of decreased capacity requirements, decreased performance requirements, and decreased power budget, by selecting and deallocating either one of the plurality of memory components or one of the plurality of memory devices and any of the plurality of memory components contained therein.

11. The system of claim 8, wherein the processing device is further to:
migrate a first portion of the allocation of memory from a first memory component of the plurality of memory components to a second memory component on a second of the pool of memory devices, wherein the migrating is triggered by:
changes in one or more of performance, capacity, and power consumption needs of the host system,
an indication that a first memory device of the plurality of memory devices has reached an endurance level threshold, or
an indication of a failure of the first memory component.

12. The system of claim 8, wherein the processing device is further to:
rebuild the allocation of memory in response to a trigger indicating changing needs of the host system by:
selecting a new plurality of host systems from the pool of host systems, the new plurality of host systems comprising a new pool of memory devices,
selecting a new plurality of memory devices from the pool of memory devices,
selecting a new plurality of memory components comprising up to two or more different media types from among the new plurality of memory devices,
aggregating the new plurality of memory components to build a new allocation of memory, and
providing, to the host system, hierarchical addresses to be used to access the new plurality of memory components implementing the new allocation of memory, the hierarchical addresses each comprising a device ID of an associated memory device,
wherein the changing needs of the host system comprise one of a newly requested geometry, a need to implement tiering, and a need to implement caching.

13. The system of claim 8, wherein the processing device is further to:
select first, second, and third memory components from among the plurality of memory components, the first, second, and third memory components being associated with multiple of the plurality of memory devices;
use the first, second, and third memory components as a redundant array of independent memory components (RAIMC);
provide, to the host system, a hierarchical address to be used to access the first memory component, the hierarchical address comprising a host ID of an associated host system and a device ID of an associated memory device;
duplicate, to the second and third memory components, data accesses addressed to the first memory component; and
store, for each data element of the third memory component, a parity reflecting an exclusive-OR (XOR) of corresponding elements of the first and second memory components, and wherein a value of ‘1’ of the parity indicates a data error.

14. The system of claim 8, wherein the plurality of memory components are heterogeneous, comprising different types of non-volatile memory components, including two or more of: single-level cell (SLC) NAND flash, multi-level cell (MLC) NAND flash, triple-level cell (TLC) NAND flash, and quad-level-cell (QLC) NAND flash, 3D XPoint, ReRAM, and NRAM (Nano-RAM, a resistive non-volatile random access memory (RAM)).

15. A non-transitory machine-readable storage medium comprising instructions that, when executed by a processing device, cause the processing device to:
receive a request to construct an allocation of memory from a host system among a pool of host systems, the pool of host systems being coupled to a pool of memory devices;
select a plurality of memory devices among the pool of memory devices;
select a plurality of memory components among the plurality of memory devices;
aggregate the plurality of memory components to implement the allocation of memory;
provide, to the host system, hierarchical addresses to be used to access the plurality of memory components implementing the allocation of memory, the hierarchical addresses each comprising a device ID of an associated memory device and a host ID of an associated host system.

16. The non-transitory machine-readable storage medium of claim 15, wherein the instructions further cause the processing device to:
expand the allocation of memory, when the one or more triggers indicate one or more of increased capacity requirements, increased performance requirements, or increased power budget, by selecting an additional memory component from among the plurality of memory devices or from another memory device of the pool of memory devices, or from an additional memory device being added to the pool of memory devices, or from an added memory device in another host system being added to the pool of host systems, and aggregating the additional memory component with the plurality of memory components already implementing the allocation of memory; and
contract the allocation of memory, when the one or more triggers indicate one or more of decreased capacity requirements, decreased performance requirements, and decreased power budget, by selecting and deallocating either one of the plurality of memory components or one of the plurality of memory devices and any of the plurality of memory components contained therein.

17. The non-transitory machine-readable storage medium of claim 15, wherein the instructions further cause the processing device to:
migrate a first portion of the allocation of memory from a first memory component of the plurality of memory components to a second memory component on a second of the pool of memory devices, wherein the migrating is triggered by:
changes in one or more of performance, capacity, and power consumption needs of the host system,
an indication that a first memory device of the plurality of memory devices has reached an endurance level threshold, or
an indication of a failure of the first memory component.

18. The non-transitory machine-readable storage medium of claim 15, wherein the instructions further cause the processing device to respond by:
rebuilding the allocation of memory in response to a trigger indicating changing needs of the host system by:
selecting a new plurality of host systems from the pool of host systems, the new plurality of host systems comprising a new pool of memory devices,
selecting a new plurality of memory devices from the new pool of memory devices,
selecting a new plurality of memory components comprising up to two or more different media types from among the new plurality of memory devices,
aggregating the new plurality of memory components to build a new allocation of memory, and
providing, to the host system, hierarchical addresses to be used to access the new plurality of memory components implementing the new allocation of memory, the hierarchical addresses each comprising a device ID of an associated memory device,
wherein the changing needs of the host system comprise one of a newly requested geometry, a need to implement tiering, and a need to implement caching.

19. The non-transitory machine-readable storage medium of claim 15, wherein the instructions further cause the processing device to:
select first, second, and third memory components from among the plurality of memory components, the first, second, and third memory components being included in a same memory device;
use the first, second, and third memory components as a redundant array of independent memory components (RAIMC);
provide, to the host system, a hierarchical address to be used to access the first memory component, the hierarchical address comprising a host ID of an associated host system and a device ID of an associated memory device;
duplicate, to the second and third memory components, data accesses addressed to the first memory component; and
store, for each data element of the third memory component, a parity reflecting an exclusive-OR (XOR) of corresponding elements of the first and second memory components, and wherein a value of ‘1’ of the parity indicates a data error.

20. The non-transitory machine-readable storage medium of claim 15, wherein the plurality of memory components are heterogeneous, comprising different types of non-volatile memory components, including two or more of: single-level cell (SLC) NAND flash, multi-level cell (MLC) NAND flash, triple-level cell (TLC) NAND flash, and quad-level-cell (QLC) NAND flash, 3D XPoint, ReRAM, and NRAM (Nano-RAM, a resistive non-volatile random access memory (RAM)).
